(19) United States
(12) Patent Application Publication
(10) Pub. No.: US 2026/0334051 A1
(43) Pub. Date: Oct. 22, 2026

(54) METAL SUPPORT FOR FLEXIBLE DISPLAY DEVICE, METHOD FOR MANUFACTURING THE SAME, AND FLEXIBLE DISPLAY DEVICE

(71) Applicant: DAI NIPPON PRINTING CO., LTD., Tokyo-to (JP)

(72) Inventors: Masao FUKUSHIMA, Tokyo-to (JP); Masanobu NAKANO, Tokyo-to (JP); Shinichiro TAKAHASHI, Tokyo-to (JP); Yoshihiro FUJITA, Tokyo-to (JP)

(73) Assignee: DAI NIPPON PRINTING CO., LTD., Tokyo-to (JP)

(21) Appl. No.: 19/109,762

(22) PCT Filed: Sep. 7, 2023
(86) PCT No.: PCT/JP2023/032631

§ 371 Date: Mar. 7, 2025

(30) Foreign Application Priority Data
Sep. 8, 2022 (JP) 2022-143294
Mar. 31, 2023 (JP) 2023-058942

(51) Int. Cl. H10K 59/80; H10K 59/12; H10K 102/00

(52) U.S. Cl. CPC H10K 59/8721; H10K 59/1201; H10K 2102/311

(57) ABSTRACT

A metal support for a flexible display device includes a first metal layer having a first surface and a second surface, and a second metal layer stacked on the second surface of the first metal layer. A main metal material constituting the first metal layer and a main metal material constituting the second metal layer are different from each other. The second metal layer has a first opening.

### TECHNICAL FIELD

The present disclosure relates to a metal support for a flexible display device, a method for manufacturing the same, and a flexible display device.

### BACKGROUND ART

In recent years, foldable display devices, such as smartphones and tablets, are known. Such display devices include a flexible display device having a bendable bending portion in a part thereof (for example, see PTLs 1 and 2).

### CITATION LIST

### Patent Literature

PTL 1: Japanese Patent No. 6603764

PTL 2: Japanese Unexamined Patent Application Publication No. 2020-86462

### SUMMARY OF INVENTION

### Technical Problem

In recent years, there has been a demand for a further reduction in the shape of a bending portion of a flexible display device when the flexible display device is folded. Specifically, there is a demand for a further reduction in the radius of curvature of the bending portion. However, a further reduction in the shape of the bending portion makes it difficult to maintain the strength of the bending portion.

The present disclosure provides a metal support for a flexible display device, a method for manufacturing the same, and a flexible display device in which the radius of curvature of a bending portion of the flexible display device can be further reduced.

The present disclosure provides a metal support for a flexible display device, a method for manufacturing the same, and a flexible display device in which the bending resistance of the bending portion of the flexible display device can be improved.

### DISCLOSURE OF INVENTION

Embodiments of the present disclosure relate to [1] to [24] below.

[1] A metal support for a flexible display device, the metal support including: a first metal layer having a first surface and a second surface; and a second metal layer stacked on the second surface of the first metal layer, wherein a main metal material constituting the first metal layer and a main metal material constituting the second metal layer are different from each other, and the second metal layer has a first opening.

[2] The metal support for a flexible display device according to [1], further including a third metal layer stacked on the first surface of the first metal layer.

[3] The metal support for a flexible display device according to [2], wherein the third metal layer has a second opening.

[4] The metal support for a flexible display device according to [2] or [3], wherein at least a part of the first opening in the second metal layer and at least a part of the second opening in the third metal layer overlap each other in plan view.

[5] The metal support for a flexible display device according to any one of [2] to [4], wherein at least a part of the first opening in the second metal layer and at least a part of the second opening in the third metal layer are shifted from each other in plan view.

[6] The metal support for a flexible display device according to [2], wherein the third metal layer has no opening.

[7] The metal support for a flexible display device according to any one of [1] to [6], wherein the second metal layer has a pattern shape portion around the first opening, and the pattern shape portion includes a portion formed in an island shape, a line shape, or a mesh shape.

[8] A flexible display device including: a display member; and the metal support for a flexible display device according to any one of [1] to [7] that supports the display member.

[9] A method for manufacturing a metal support for a flexible display device, the method including: a step of preparing a laminate including a first metal layer having a first surface and a second surface, and a second metal layer stacked on the second surface of the first metal layer, a main metal material constituting the first metal layer and a main metal material constituting the second metal layer being different from each other; a step of providing a second protective layer having a second protective layer opening on the second metal layer of the laminate; and a step of etching the second metal layer of the laminate to form a first opening in the second metal layer.

[10] The method for manufacturing a metal support for a flexible display device according to [9], wherein the laminate further includes a third metal layer stacked on the first surface of the first metal layer, and the method for manufacturing a metal support for a flexible display device further includes a step of providing a first protective layer on the third metal layer.

[11] The method for manufacturing a metal support for a flexible display device according to [10], wherein the first protective layer has a first protective layer opening, and in the step of etching, a second opening is formed in the third metal layer.

[12] The method for manufacturing a metal support for a flexible display device according to [10], wherein the first protective layer has no opening, and in the step of etching, a second opening is not formed in the third metal layer.

[13] A metal support for a flexible display device, the metal support including: a first layer having a first surface and a second surface; and a second layer bonded to the second surface of the first layer, wherein the second layer has a first hole that is open at least on a side opposite from a bonding surface to the first layer.

[14] The metal support for a flexible display device according to [13], wherein the first layer has no hole.

[15] The metal support for a flexible display device according to [13] or [14], wherein the first hole is a through-hole.

[16] The metal support for a flexible display device according to [13] or [15], wherein the first layer has a second hole.

[17] The metal support for a flexible display device according to [16], wherein the second hole is open at least on the second surface side, and the second layer is accommodated in the second hole.

[18] The metal support for a flexible display device according to [16], wherein the second hole overlaps the first hole in plan view.

[19] The metal support for a flexible display device according to any one of [13] to [18], further including a third layer bonded to the first surface of the first layer.

[20] The metal support for a flexible display device according to [19], wherein the third layer has a third hole.

[21] The metal support for a flexible display device according to [19] or [20], wherein the first layer has a fourth hole, and the third layer is accommodated in the fourth hole.

[22] The metal support for a flexible display device according to any one of [13] to [18], further including a third layer bonded to the second layer.

[23] A flexible display device including: a display member; and the metal support for a flexible display device according to any one of [13] to [23] that supports the display member.

[24] A method for manufacturing a metal support for a flexible display device, the method including: a step of preparing a second layer having a first hole; a step of preparing a first layer having a first surface and a second surface; and a step of bonding the second layer to the second surface of the first layer such that the first hole is open at least on a side opposite from a bonding surface to the first layer.

According to the present disclosure, it is possible to further reduce the radius of curvature of the bending portion of the flexible display device. According to the present disclosure, it is possible to improve the bending resistance of the bending portion of the flexible display device.

### BRIEF DESCRIPTION OF DRAWINGS

FIG. 1 is a perspective view showing a flexible display device according to a first embodiment.

FIG. 2 is a plan view showing the flexible display device according to the first embodiment.

FIG. 3 is a sectional view (a sectional view taken along line III-III in FIG. 2) showing the flexible display device (in an unfolded state) according to the first embodiment.

FIG. 4 is a sectional view showing the flexible display device (in a folded state) according to the first embodiment.

FIG. 5 is a plan view showing a metal support for a flexible display device according to the first embodiment.

FIG. 6 is a partial sectional view (a sectional view taken along line VI-VI in FIG. 5) showing the metal support for a flexible display device according to the first embodiment.

FIG. 7(A) to 7(C) are plan views showing a metal support for a flexible display device according to a modification of the first embodiment.

FIG. 8(A) to 8(D) are sectional views showing a method for manufacturing the metal support for a flexible display device according to the first embodiment.

FIG. 9(A) to 9(D) are sectional views showing a metal support for a flexible display device according to a modification of the first embodiment.

FIG. 10 is a perspective view showing a flexible display device according to a second embodiment.

FIG. 11 is a plan view showing the flexible display device according to the second embodiment.

FIG. 12 is a sectional view (a sectional view taken along line XII-XII in FIG. 11) showing the flexible display device (in an unfolded state) according to the second embodiment.

FIG. 13 is a sectional view showing the flexible display device (in a folded state) according to the second embodiment.

FIG. 14 is a plan view showing a metal support for the flexible display device according to the second embodiment.

FIG. 15 is a sectional view (a sectional view taken along line XV-XV in FIG. 14) showing the metal support for the flexible display device according to the second embodiment.

FIG. 16 is a partially enlarged sectional view (a sectional view taken along line XVI-XVI in FIG. 14) showing the metal support for the flexible display device according to the second embodiment.

FIG. 17 is a plan view showing a metal support for a flexible display device according to a modification of the second embodiment.

FIG. 18(A) to 18(F) are sectional views showing a method for manufacturing the metal support for the flexible display device according to the second embodiment.

FIG. 19 is a cross-sectional view showing a metal support for a flexible display device according to a first modification of the second embodiment.

FIG. 20 is a cross-sectional view showing a metal support for a flexible display device according to a second modification of the second embodiment.

FIG. 21 is a cross-sectional view showing a metal support for a flexible display device according to a third modification of the second embodiment.

FIG. 22 is a cross-sectional view showing a metal support for a flexible display device according to a fourth modification of the second embodiment.

FIG. 23 is a cross-sectional view showing a metal support for a flexible display device according to a fifth modification of the second embodiment.

FIG. 24 is a cross-sectional view showing a metal support for a flexible display device according to a sixth modification of the second embodiment.

FIG. 25 is a cross-sectional view showing a metal support for a flexible display device according to a seventh modification of the second embodiment.

### DESCRIPTION OF EMBODIMENTS

### First Embodiment

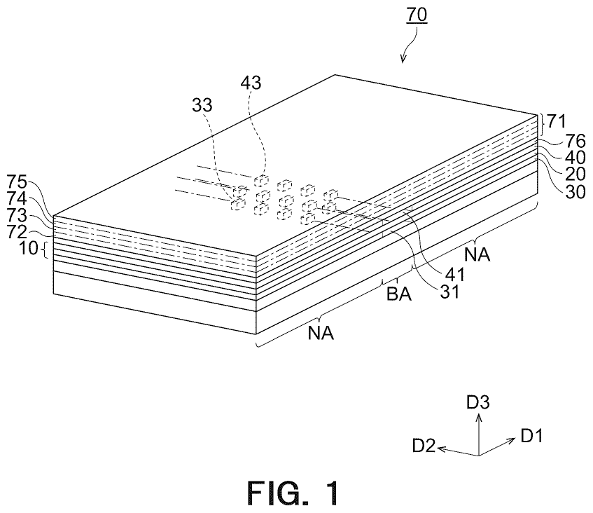

A first embodiment will be described below with reference to FIGS. 1 to 9. In the drawings, the same parts are denoted by the same reference numerals, and a detailed description thereof may be partially omitted.

In the specification, a first direction D1 is a direction located on a plane parallel to a main surface of a metal support 10 for a flexible display device or a flexible display device 70 and perpendicular to a folding center line FL. A second direction D2 is a direction located on a plane parallel to the main surface of the metal support 10 for a flexible display device or the flexible display device 70 and parallel to the folding center line FL. The first direction D1 and the second direction D2 may be directions parallel to the sides of the metal support 10 for a flexible display device or the flexible display device 70. The first direction D1 and the second direction D2 are orthogonal to each other. A third direction D3 is a direction perpendicular to both the first direction D1 and the second direction D2 and parallel to a thickness direction of the metal support 10 for a flexible display device or the flexible display device 70.

### Structure of Metal Support for Flexible Display Device

First, the outline of the flexible display device according to this embodiment will be described with reference to FIGS. 1 to 4. FIGS. 1 to 4 are views showing the flexible display device according to this embodiment.

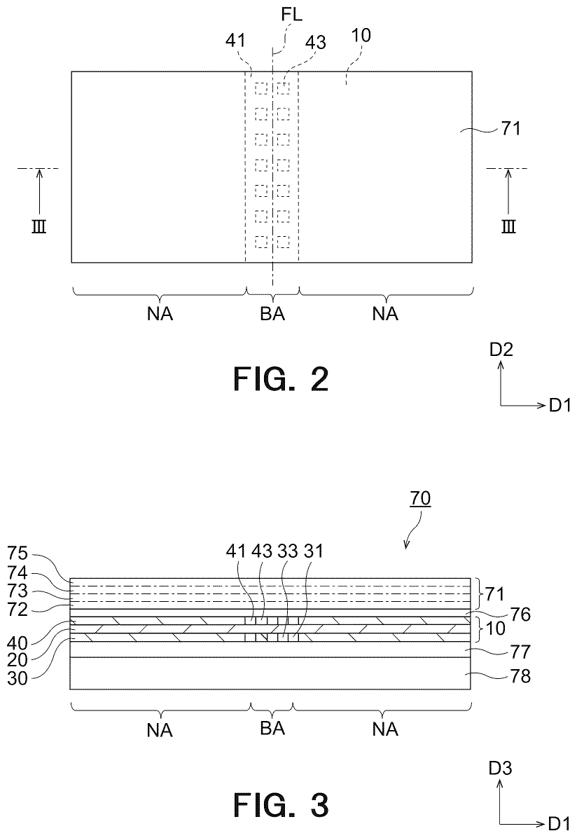

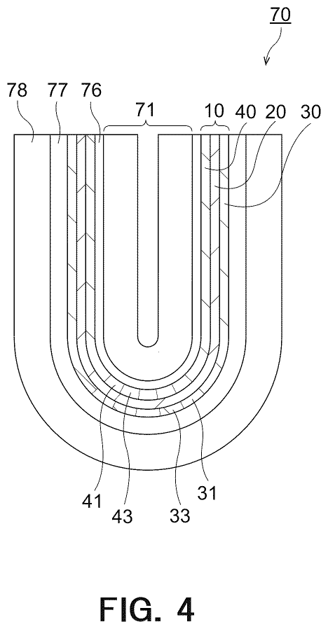

The flexible display device 70 shown in FIGS. 1 and 2 may be, for example, an organic EL display device. The flexible display device 70 is flexible and has a foldable structure. Specifically, the flexible display device 70 can be in a folded state, (see FIG. 4) in which the flexible display device 70 is folded, and in an unfolded state (see FIGS. 2 and 3), in which the flexible display device 70 is open. The folded state is a state in which the flexible display device 70 is folded along the folding center line FL. In the folded state, the flexible display device 70 is folded in a direction in which outer surfaces of a display member 71 approach each other. The structure is not limited to this, and the flexible display device 70 may be folded in a direction in which outer surfaces of a housing 78 approach each other. The unfolded state is a state in which the flexible display device 70 is open without being folded. In the unfolded state, the entire surface of the display member 71 is located substantially on the same plane. This flexible display device 70 may be a thin electronic apparatus having a part for displaying an image. Such an electronic device may be a mobile terminal device, such as a smartphone or a tablet.

As shown in FIG. 3, the flexible display device 70 includes the display member 71 and the metal support 10 for a flexible display device (hereinbelow, also simply referred to as the metal support 10) that supports the display member 71. A buffer layer 76, such as a cushion sheet, is provided between the display member 71 and the metal support 10. A heat dissipation layer 77 is disposed on the surface of the metal support 10 opposite from the display member 71. Furthermore, the display member 71, the buffer layer 76, the metal support 10, and the heat dissipation layer 77 are supported by the housing 78.

The display member 71 includes a support base 72, a thin film transistor (TFT) 73, an organic EL element 74, and a sealing resin 75. The thin film transistor 73 is disposed on the support base 72. The organic EL element 74 is disposed on the thin film transistor 73. The sealing resin 75 is disposed on the organic EL element 74.

The support base 72 supports the entire display member 71 and may be a flexible film. A synthetic resin material, such as polyethylene terephthalate, may be used as the support base 72. The thin film transistor 73 is used for driving the organic EL element 74 and controls a voltage applied to an electrode of the organic EL element 74. The organic EL element 74 displays an image or the like by emitting light. The organic EL element 74 is electrically connected to the thin film transistor 73. The organic EL element 74 may be referred to as a light emitting part. The organic EL element 74 may include a reflective electrode, an organic light-emitting layer, and a transparent electrode (not shown). The sealing resin 75 is used for sealing the organic EL element 74 to protect the organic EL element 74. The display member 71 is not limited to the organic EL display device. For example, the display member 71 may be another display device having a function of emitting light. The display member 71 may be a micro LED display device including micro LED elements (light emitting bodies).

The buffer layer 76 is a layer that reduces stress applied to the display member 71 when the flexible display device 70 is folded. The buffer layer 76 may be a layer of a resin material having elasticity, such as a silicone resin, a polyurethane resin, or an epoxy resin. The metal support 10 is a member that increases the flexural strength when the flexible display device 70 is folded. The structure of the metal support 10 will be described below.

The heat dissipation layer 77 is a layer for releasing heat from the display member 71 to the outside. The heat dissipation layer 77 may be a metal layer made of copper, nickel, or the like. The heat dissipation layer 77 may be a plating layer formed by electrolytic plating. The housing 78 accommodates and protects the display member 71, the buffer layer 76, the metal support 10, and the heat dissipation layer 77. The housing 78 has such a structure that it can be folded at the folding center line FL.

The flexible display device 70 includes a bending area BA and non-bending areas NA. The bending area BA is an area that is physically deformed when the flexible display device 70 is brought into the folded state (see FIG. 4). The folding center line FL is located at substantially the center of the bending area BA. The non-bending areas NA are areas that are not substantially deformed when the flexible display device 70 is brought into the folded state (see FIG. 4). The non-bending areas NA are present on both sides of the bending area BA in the first direction D1. The lengths of the two non-bending areas NA in the first direction D1 may be substantially equal. The structure is not limited to this, and the lengths of the two non-bending areas NA in the first direction D1 may be different from each other. The bending area BA is located at the center of the flexible display device 70 in the first direction D1. The structure is not limited to this, and the bending area BA may be located at a position other than the center of the flexible display device 70 in the first direction D1.

### Structure of Metal Support for Flexible Display Device

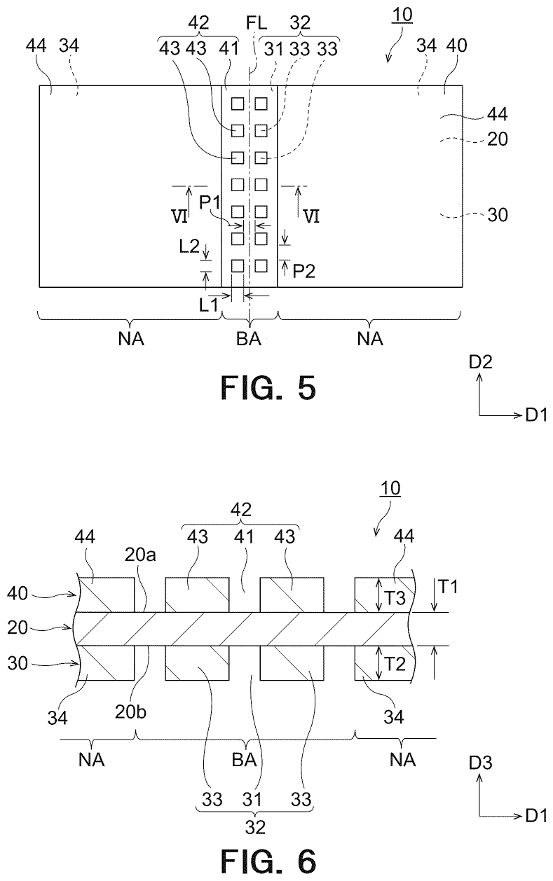

Next, the outline of the metal support for a flexible display device according to this embodiment will be described with reference to FIGS. 5 and 6. FIGS. 5 and 6 are views showing the metal support for a flexible display device according to this embodiment.

As shown in FIGS. 5 and 6, the metal support 10 includes a first metal layer 20, a second metal layer 30, and a third metal layer 40. In other words, the metal support 10 is a three-layer laminate. The first metal layer 20 has a first surface 20a and a second surface 20b. The first surface 20a is a surface facing the display member 71 of the flexible display device 70. The second surface 20b is a surface facing the heat dissipation layer 77 of the flexible display device 70. The first surface 20a and the second surface 20b are each parallel to a plane defined by a first direction D1 axis and a second direction D2 axis. The second metal layer 30 is disposed on the second surface 20b of the first metal layer 20. The third metal layer 40 is stacked on the first surface 20a of the first metal layer 20. The main metal material constituting the first metal layer 20 and the main metal material constituting the second metal layer 30 are different from each other. The second metal layer 30 has a first opening 31 that is open on the side opposite from the first metal layer 20.

The metal support 10 has a bending area BA and non-bending areas NA. The bending area BA is an area that is physically deformed when the flexible display device 70 is brought into the folded state (see FIG. 4). The folding center line FL is located at substantially the center of the bending area BA. The non-bending areas NA are areas that are not substantially deformed when the flexible display device 70 is brought into the folded state (see FIG. 4). The bending area BA and the non-bending areas NA correspond to the bending area BA and the non-bending areas NA of the flexible display device 70 described above, respectively.

The first metal layer 20 is a member that increases the flexural strength when the flexible display device 70 is folded. The first metal layer 20 holds the second metal layer 30 and the third metal layer 40. The first metal layer 20 has a rectangular shape in plan view. In the rectangle, a pair of long sides are parallel to the first direction D1, and a pair of short sides are parallel to the second direction D2. The structure is not limited to this, and the pair of short sides may be parallel to the first direction D1, and the pair of long sides may be parallel to the second direction D2. Corners of the rectangle may be rounded. The first metal layer 20 may have a square shape, a polygonal shape, or a circular shape in plan view. The shape in plan view of the first metal layer 20 may correspond to the shape in plan view of the flexible display device 70. In this case, the shape in plan view of the first metal layer 20 may be the same as the shape in plan view of the flexible display device 70. Alternatively, the shape in plan view of the first metal layer 20 may be smaller than the shape in plan view of the flexible display device 70.

The first metal layer 20 has a flexible and bendable thin plate shape. In this specification, the term “flexible” means “capable of being folded with a radius of curvature of at least 5.0 mm or less, preferably 3.0 mm or less”.

A thickness T1 of the first metal layer 20 may be 10 μm or more, or may be 15 μm or more. By setting the thickness T1 of the first metal layer 20 to 10 μm or more, the flexural strength of the first metal layer 20 can be maintained. The thickness T1 of the first metal layer 20 may be 40 μm or less, or may be 30 μm or less. By setting the thickness T1 of the first metal layer 20 to 40 μm or less, it is possible to inhibit the flexible display device 70 incorporating the metal support 10 from becoming excessively thick.

The first metal layer 20 is made of a metal. The first metal layer 20 contains a main metal material. An iron alloy, such as stainless steel, may be used as a main metal material of the first metal layer 20. The use of stainless steel as the main metal material of the first metal layer 20 provides the first metal layer 20 with good spring properties, making it easy to fold the first metal layer 20. In the specification, the “main metal material” refers to a metal material contained in a certain member in an amount of more than 50 mass %, preferably more than 80 mass %.

The second metal layer 30 is stacked on the second surface 20b of the first metal layer 20. The second metal layer 30 is bonded to the first metal layer 20. The second metal layer 30 may be stacked on the first metal layer 20 by roll bonding, diffusion bonding, or deposition of metal by plating, as described below. The second metal layer 30 increases the strength of the metal support 10. The second metal layer 30 is provided at least in the bending area BA of the first metal layer 20. The second metal layer 30 may be provided on the entire second surface 20b of the first metal layer 20 including the bending area BA, or may be provided on a part of the second surface 20b of the first metal layer 20. The second metal layer 30 may be directly stacked on the second surface 20b of the first metal layer 20, or may be stacked on the first metal layer 20 with another layer therebetween. A thickness T2 of the second metal layer 30 may be 100 μm or less, or may be 50 μm or less. The thickness T2 of the second metal layer 30 may be less than the thickness T1 of the first metal layer 20.

The second metal layer 30 has a first opening 31 that is open on the side opposite from the first metal layer 20. In this case, the first opening 31 is a penetrating opening penetrating the second metal layer 30 in the thickness direction. Specifically, a portion of the second surface 20b of the first metal layer 20 is exposed to the outside through the first opening 31. The first opening 31 may be a non-penetrating opening that does not penetrate the second metal layer 30 in the thickness direction, as long as the first opening 31 is open on the side opposite from the first metal layer 20. As shown in FIG. 5, the outer periphery of the first opening 31 does not necessarily have to be formed in an annular shape. In other words, the first opening 31 may reach the outer edge of the second metal layer 30.

The second metal layer 30 has a first pattern shape portion 32 around the first opening 31. The first pattern shape portion 32 is provided at a position corresponding to the bending area BA. The first pattern shape portion 32 includes first island-shaped portions 33, which are portions formed in an island shape. The first pattern shape portion 32 has the first opening 31 and the plurality of first island-shaped portions 33 each having an annular outer periphery. The first opening 31 is formed around the first island-shaped portions 33. The first opening 31 surrounds the entire outer periphery of each first island-shaped portion 33. The first island-shaped portions 33 are disposed at intervals in each of the first direction D1 and the second direction D2. The multiple first island-shaped portions 33 are aligned in both the first direction D1 and the second direction D2. More specifically, the plurality of first island-shaped portions 33 are disposed at intervals in the first direction D1 and are disposed at intervals in the second direction D2. The interval P1 between the first island-shaped portions 33 in the first direction D1 may be 5 μm or more, and may be 10 μm or more. The interval P1 between the first island-shaped portions 33 in the first direction D1 may be 500 μm or less, and may be 100 μm or less. The interval P2 between the first island-shaped portions 33 in the second direction D2 may be 5 μm or more, and may be 10 μm or more. The interval P2 between the first island-shaped portions 33 in the second direction D2 may be 500 μm or less, and may be 100 μm or less.

Each first island-shaped portion 33 has a substantially square shape in plan view. The structure is not limited to this, and the first island-shaped portions 33 may have, for example, a polygonal shape or a circular shape in plan view. A length L1 of the first island-shaped portion 33 in the first direction D1 may be 5 μm or more, or may be 10 μm or more. The length L1 of the first island-shaped portion 33 in the first direction D1 may be 500 μm or less, or may be 100 μm or less. A length L2 of the first island-shaped portion 33 in the second direction D2 may be 5 μm or more, or may be 10 μm or more. The length L2 of the first island-shaped portion 33 in the second direction D2 may be 500 μm or less, or may be 100 μm or less.

The second metal layer 30 includes a pair of first peripheral portions 34. The first peripheral portions 34 are provided at positions corresponding to the non-bending areas NA. The first pattern shape portion 32 is located between the pair of first peripheral portions 34. Although the first peripheral portions 34 are provided with no opening, there may be an opening in the first peripheral portions 34.

The second metal layer 30 is made of a metal. The second metal layer 30 contains a main metal material. The main metal material of the second metal layer 30 is different from the main metal material of the first metal layer 20. The main metal material of the second metal layer 30 may be, for example, copper (Cu), nickel (Ni), or an alloy thereof. When copper is used as the main metal material of the second metal layer 30, the workability of the second metal layer 30 is improved, making microfabrication possible. In addition, the thermal conductivity of the second metal layer 30 can be improved. When nickel is used as the main metal material of the second metal layer 30, the surface hardness of the second metal layer 30 is increased, making it possible to receive an impact when the flexible display device 70 is used.

The third metal layer 40 is stacked on the first surface 20a of the first metal layer 20. The third metal layer 40 is bonded to the first metal layer 20. The third metal layer 40 may be stacked on the first metal layer 20 by roll bonding, diffusion bonding, or deposition of metal by plating, as described below. The third metal layer 40 increases the strength of the metal support 10. The third metal layer 40 is provided at least in the bending area BA of the first metal layer 20. The third metal layer 40 may be provided on the entire first surface 20a of the first metal layer 20 including the bending area BA, or may be provided on a part of the first surface 20a of the first metal layer 20. The third metal layer 40 may be directly stacked on the first surface 20a of the first metal layer 20, or may be stacked on the first metal layer 20 with another layer therebetween. A thickness T3 of the third metal layer 40 may be 100 μm or less, or may be 50 μm or less. The thickness T3 of the third metal layer 40 may be less than the thickness T1 of the first metal layer 20. The thickness T3 of the third metal layer 40 may be equal to the thickness T2 of the second metal layer 30. Alternatively, the thickness T3 of the third metal layers 40 may be different from the thickness T2 of the second metal layer 30.

The third metal layer 40 has a second opening 41 that is open on the side opposite from the first metal layer 20. In this case, the second opening 41 is a penetrating opening penetrating the third metal layer 40 in the thickness direction. Specifically, a portion of the first surface 20a of the first metal layer 20 is exposed to the outside through the second opening 41. The second opening 41 may be a non-penetrating opening that does not penetrate the third metal layer 40 in the thickness direction, as long as the second opening 41 is open on the side opposite from the first metal layer 20. As shown in FIG. 5, the outer periphery of the second opening 41 does not necessarily have to be formed in an annular shape. In other words, the second opening 41 may reach the outer edge of the third metal layer 40. In the example shown in FIGS. 5 and 6, the second opening 41 has the same shape in plan view as that of the first opening 31. Specifically, the entire first opening 31 and the entire second opening 41 overlap each other in plan view. The structure is not limited to this, and at least a portion of the first opening 31 and at least a portion of the second opening 41 may overlap each other in plan view.

The third metal layer 40 has a second pattern shape portion 42 around the second opening 41. The second pattern shape portion 42 is provided at a position corresponding to the bending area BA. The second pattern shape portion 42 includes second island-shaped portions 43, which are portions formed in an island shape. The second pattern shape portion 42 has the second opening 41 and the plurality of second island-shaped portions 43 each having an annular outer periphery. The second opening 41 is formed around the second island-shaped portions 43. The second opening 41 surrounds the entire outer periphery of each second island-shaped portion 43. The second island-shaped portions 43 are disposed at intervals in each of the first direction D1 and the second direction D2. In the example shown in FIGS. 5 and 6, the plurality of second island-shaped portions 43 have the same shape in plan view as the plurality of first island-shaped portions 33. Specifically, the positions and shapes of the first opening 31 and the first island-shaped portions 33 are the same as the positions and shapes of the second opening 41 and the second island-shaped portions 43. The structure is not limited to this, and the positions or shapes of the first opening 31 and the first island-shaped portions 33 may be different from the positions or shapes of the second opening 41 and the second island-shaped portions 43.

The third metal layer 40 includes a pair of second peripheral portions 44. The second peripheral portions 44 are provided at positions corresponding to the non-bending areas NA. The second pattern shape portion 42 is located between the pair of second peripheral portions 44. Although the second peripheral portions 44 are provided with no opening, there may be an opening in the second peripheral portions 44.

The third metal layer 40 is made of a metal. The third metal layer 40 contains a main metal material. The main metal material of the third metal layer 40 is different from the main metal material of the first metal layer 20. The main metal material of the third metal layer 40 may be, for example, copper (Cu), nickel (Ni), or an alloy thereof. When copper is used as the main metal material of the third metal layer 40, the workability of the third metal layer 40 is improved, making microfabrication possible. In addition, the thermal conductivity of the third metal layer 40 can be improved. When nickel is used as the main metal material of the third metal layer 40, the surface hardness of the third metal layer 40 is increased, making it possible to receive an impact when the flexible display device 70 is used. The main metal material of the third metal layer 40 may be the same as the main metal material of the second metal layer 30, or may be different from the main metal material of the second metal layer 30.

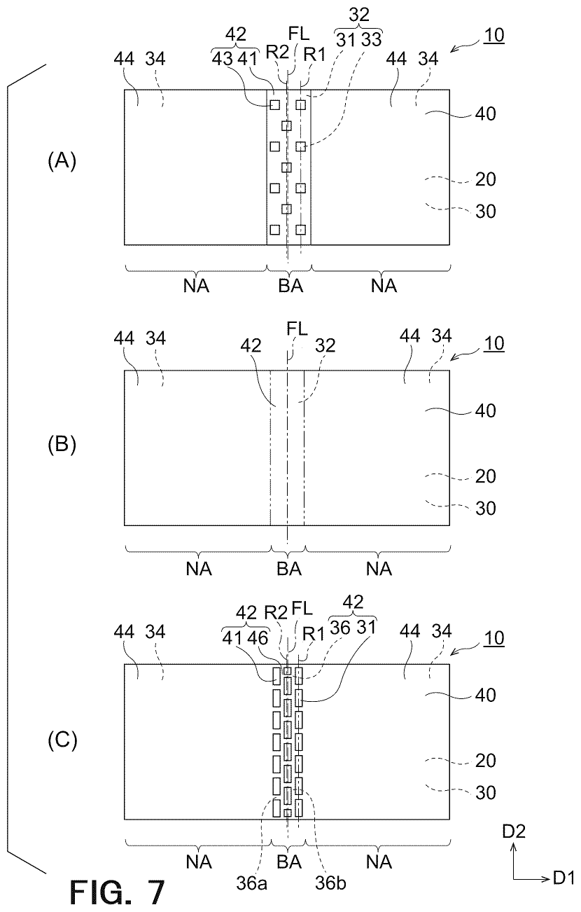

FIG. 7(A) to 7(C) are plan views showing modifications of the metal support 10. As shown in FIG. 7(A), the first pattern shape portion 32 may include a plurality of first island-shaped portions 33 formed in an island shape, and the plurality of first island-shaped portions 33 may be arranged alternately (in a staggered manner). In this case, the plurality of first island-shaped portions 33 include the first island-shaped portions 33 in a first row R1 arranged at intervals in the second direction D2 and the first island-shaped portions 33 in a second row R2 arranged at intervals in the second direction D2. The first island-shaped portions 33 in the first row R1 and the first island-shaped portions 33 in the second row R2 are arranged so as to be shifted from each other in the second direction D2. In this case, because the plurality of first island-shaped portions 33 are arranged alternately, it is possible to inhibit the stress from concentrating on a specific portion when the flexible display device 70 is folded. In the example shown in FIG. 7(A), the third metal layer 40 has the same shape in plan view as that of the second metal layer 30. The structure is not limited to this, and the third metal layer 40 may have a shape in plan view different from that of the second metal layer 30.

As shown in FIG. 7(B), the first pattern shape portion 32 may include a first line-shaped portion, which is a portion formed in a line shape. The first pattern shape portion 32 includes a plurality of first line-shaped portions in a region surrounded by a virtual line in FIG. 7(B). In this case, the plurality of first line-shaped portions are disposed at intervals in the first direction D1. Each of the first line-shaped portions extends in a line shape in the second direction D2. Because this increases the area of the first metal layer 20 covered by the plurality of first line-shaped portions, it is possible to increase the flexural strength when the flexible display device 70 is folded. Each of the first line-shaped portions may extend linearly in the first direction D1. The second pattern shape portion 42 of the third metal layer 40 includes a plurality of second line-shaped portions 45. In the example shown in FIG. 7(B), the third metal layer 40 has the same shape in plan view as that of the second metal layer 30. The structure is not limited to this, and the third metal layer 40 may have a shape in plan view different from that of the second metal layer 30.

As shown in FIG. 7(C), the first pattern shape portion 32 may include a first mesh-like portion 36, which is a portion formed in a mesh shape. In this case, the first mesh-like portion 36 may be formed of one member. The first mesh-like portion 36 includes a first direction portion 36a extending in the first direction and a second direction portion 36b extending in the second direction. The first openings 31 are formed so as to be surrounded by the first direction portions 36a and the second direction portions 36b. The plurality of first openings 31 include the first openings 31 in a first row R1 arranged at intervals in the second direction D2 and the first openings 31 in a second row R2 arranged at intervals in the second direction D2. The first openings 31 in the first row R1 and the first openings 31 in the second row R2 are arranged so as to be shifted from each other in the second direction D2. Specifically, the center points of the first openings 31 are arranged in an oblique lattice pattern. In this case, because the area of the second metal layer 30 covering the first metal layer 20 is large, it is possible to increase the flexural strength when the flexible display device 70 is folded. Furthermore, because the plurality of first openings 31 are arranged alternately, it is possible to alleviate stress concentration on a specific portion when the flexible display device 70 is folded. The center points of the first openings 31 may be arranged in a square lattice pattern or a rectangular lattice pattern. The second pattern shape portion 42 of the third metal layer 40 has a second mesh-like portion 46 formed in a mesh shape. In the example shown in FIG. 7(C), the third metal layer 40 has the same shape in plan view as that of the second metal layer 30. The structure is not limited to this, and the third metal layer 40 may have a shape in plan view different from that of the second metal layer 30.

### Method for Manufacturing Metal Support for Flexible Display Device

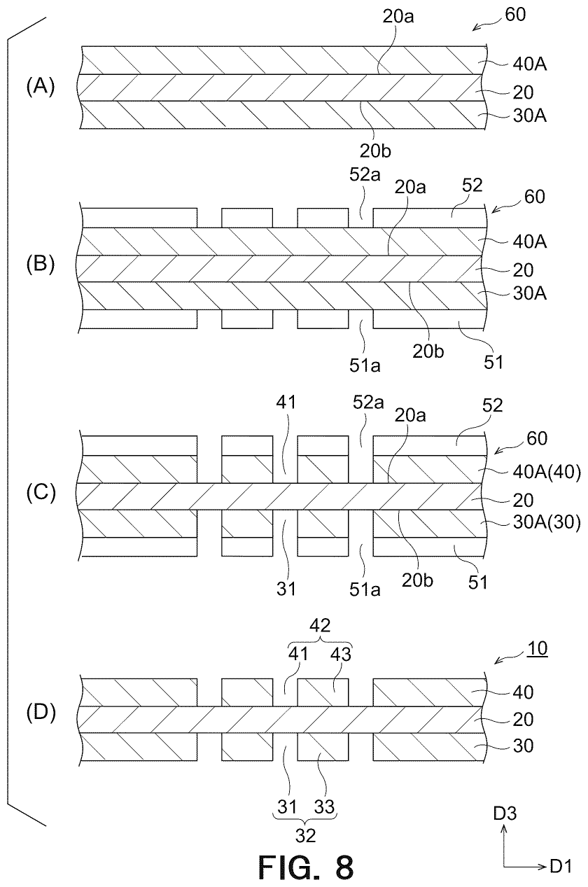

Next, a method for manufacturing the metal support 10 shown in FIGS. 5 and 6 will be described with reference to FIG. 8(A) to 8(D).

First, as shown in FIG. 8(A), a laminate 60 including the first metal layer 20, a second metal layer 30A, and a third metal layer 40A is prepared. The second metal layer 30A is in a state before being provided with an opening and is stacked on the second surface 20b of the first metal layer 20. Similarly, the third metal layer 40A is in a state before being provided with an opening and is stacked on the first surface 20a of the first metal layer 20.

The method for manufacturing the laminate 60 is not limited. For example, the laminate 60 may be a clad material. In this case, the laminate 60 may be produced by rolling, while applying pressure, the first metal layer 20, the second metal layer 30A, and the third metal layer 40A, and bonding them together. Alternatively, the laminate 60 may be produced by diffusion-bonding the first metal layer 20, the second metal layer 30A, and the third metal layer 40A. Alternatively, the laminate 60 may be produced by forming the second metal layer 30A and the third metal layer 40A on the first metal layer 20 by plating.

Next, as shown in FIG. 8(B), a first protective layer 51 and a second protective layer 52 are provided on the laminate 60. More specifically, the first protective layer 51 having first protective layer openings 51a is provided on the second metal layer 30A, and the second protective layer 52 having second protective layer openings 52a is provided on the third metal layer 40A. The first protective layer 51 and the second protective layer 52 may be resist layers. At this time, first, a photosensitive resist is applied to the entire second metal layer 30A and the entire third metal layer 40A, and is dried. Subsequently, the photosensitive resist on the second metal layer 30A and the third metal layer 40A is exposed through a photomask and developed. In this way, the first protective layer 51 having the first protective layer openings 51a is formed on the second metal layer 30A, and the second protective layer 52 having the second protective layer openings 52a is formed on the second surface 20b. The shape in plan view of the first protective layer openings 51a corresponds to the shape in plan view of the first openings 31. The shape in plan view of the second protective layer openings 52a corresponds to the shape in plan view of the second openings 41.

Next, as shown in FIG. 8(C), the second metal layer 30A is etched with an etchant using the first protective layer 51 as a corrosion-resistant film. Similarly, the third metal layer 40A is etched with an etchant using the second protective layer 52 as a corrosion-resistant film. The etchant can be appropriately selected depending on the materials of the second metal layer 30A and the third metal layer 40A. For example, when Cu is used as the second metal layer 30A and the third metal layer 40A, the second metal layer 30A and the third metal layer 40A may be subjected to spray etching using a ferric chloride aqueous solution as an etchant. In this way, the first openings 31 penetrating the second metal layer 30A are formed in the second metal layer 30A. Similarly, the second openings 41 penetrating the third metal layer 40A are formed in the third metal layer 40A. The main metal material of the first metal layer 20 is different from the main metal materials of the second metal layer 30A and the third metal layer 40A. Hence, the first metal layer 20 is not etched.

Thereafter, as shown in FIG. 8(D), the first protective layer 51 on the second metal layer 30 and the second protective layer 52 on the third metal layer 40 are peeled away. In this way, the metal support 10 shown in FIGS. 5 and 6 is obtained.

As described above, according to this embodiment, the metal support 10 includes the first metal layer 20 and the second metal layer 30, and the second metal layer 30 has the first openings 31. This increases the flexibility of the bending area BA of the flexible display device 70 when the metal support 10 is incorporated into the flexible display device 70. As a result, it is possible to make the shape of the bending area BA when the flexible display device 70 is folded even smaller. In other words, the radius of curvature of the bending area BA can be further reduced.

Furthermore, according to this embodiment, because the second metal layer 30 is stacked on the first metal layer 20, the strength of the metal support 10 is increased. Furthermore, the heat dissipation from the second metal layer 30 is increased.

Furthermore, according to this embodiment, the third metal layer 40 is stacked on the first surface 20a of the first metal layer 20. By uniformly sandwiching the first metal layer 20 between the second metal layer 30 and the third metal layer 40 in this way, it is possible to inhibit the metal support 10 before being incorporated into the flexible display device 70 from warping. The metal support 10 may include four or more metal layers.

According to this embodiment, the third metal layer 40 has the second openings 41. This increases the flexibility of the bending area BA of the flexible display device 70 when the metal support 10 is incorporated into the flexible display device 70.

According to this embodiment, the second metal layer 30 has a portion formed in an island shape, a line shape, or a mesh shape. In this case, a space (first opening 31) is formed between the first island-shaped portions 33, between the first line-shaped portions, or inside the first mesh-shaped portion 36. This suppresses a decrease in flexibility of the metal support 10 in the bending area BA, compared with the case where the entire bending area BA of the metal support 10 is covered with a metal.

### Modifications of First Embodiment

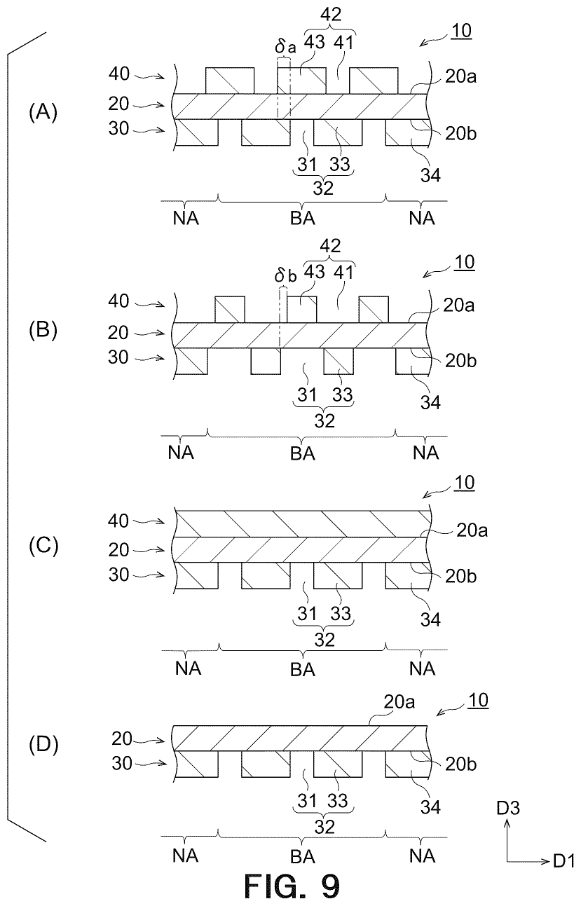

Next, modifications of the metal support 10 will be described with reference to FIG. 9(A) to 9(D). FIG. 9(A) to 9(D) are cross-sectional views showing modifications of the metal support 10. In FIG. 9(A) to 9(D), the same parts as those in the embodiment shown in FIGS. 1 to 8 are denoted by the same reference numerals, and detailed description thereof will be omitted.

As shown in FIG. 9(A), the first openings 31 in the second metal layer 30 and the second openings 41 in the third metal layer 40 may be formed so as to be shifted from each other in plan view. In this case, the first openings 31 and the second openings 41 are arranged such that the entirety of the first openings 31 and the entirety of the second openings 41 do not overlap each other in plan view. An overlap width da between the metal portion of the first pattern shape portion 32 and the metal portion of the second pattern shape portion 42 may be 1 μm or more and 50 μm or less. In this way, because the first openings 31 and the second openings 41 are formed so as to be shifted from each other in plan view, there is no portion, in the first metal layer 20, that is not covered by either the second metal layer 30 or the third metal layer 40. This suppresses stress concentration on a specific portion of the first metal layer 20 when the flexible display device 70 is folded.

As shown in FIG. 9(B), the first openings 31 in the second metal layer 30 and the second openings 41 in the third metal layer 40 may be formed so as to be shifted from each other in plan view. In this case, the first openings 31 and the second openings 41 are arranged such that the first openings 31 and the second openings 41 partially overlap each other in plan view. An overlap width δb between the first opening 31 and the second opening 41 may be 1 μm or more and 50 μm or less. This suppresses stress concentration on a specific portion of the first metal layer 20 and increases the flexibility of the bending area BA of the metal support 10 when the flexible display device 70 is folded.

As shown in FIG. 9(C), the third metal layer 40 may have no second openings 41. The third metal layer 40 spreads over at least the entire bending area BA without a gap. The third metal layer 40 may be spread over the entire first surface 20a without a gap. Because the third metal layer 40 has no openings, the third metal layer 40 side of the metal support 10 can be made flat, and thus, the display member 71 can be attached to an even planar surface of the metal support 10.

When the metal support 10 shown in FIG. 9(C) is produced, in the step of providing the first protective layer 51 and the second protective layer 52 on the laminate 60 described above (see FIG. 8(B)), the second protective layer 52 having no openings (second protective layer openings 52a) is used. By doing so, openings are prevented from being formed in the third metal layer 40A during the above-described etching (see FIG. 8(C)).

As shown in FIG. 9(D), the metal support 10 may have no third metal layer 40. In this case, the metal support 10 includes the first metal layer 20 and the second metal layer 30. In other words, the metal support 10 is a two-layer laminate. The first surface 20a of the first metal layer 20 is entirely exposed to the outside. Because the metal support 10 has no third metal layer 40, the first surface 20a side of the metal support 10 can be made flat, and thus, the display member 71 can be attached to an even planar surface of the metal support 10. Furthermore, the metal support 10 can be made thin.

When the metal support 10 shown in FIG. 9(D) is produced, in the step of providing the first protective layer 51 and the second protective layer 52 on the laminate 60 (see FIG. 8(B)), the second protective layer 52 is not provided on the third metal layer 40A. As a result, the entire third metal layer 40A is removed by etching during the above-described etching (see FIG. 8(C)). Alternatively, a laminate including two layers, namely, the first metal layer 20 and the second metal layer 30A, may be used as the laminate 60 described above (see FIG. 8(A)). By doing so, the two layer metal support 10 including the first metal layer 20 and the second metal layer 30 is obtained.

### Second Embodiment

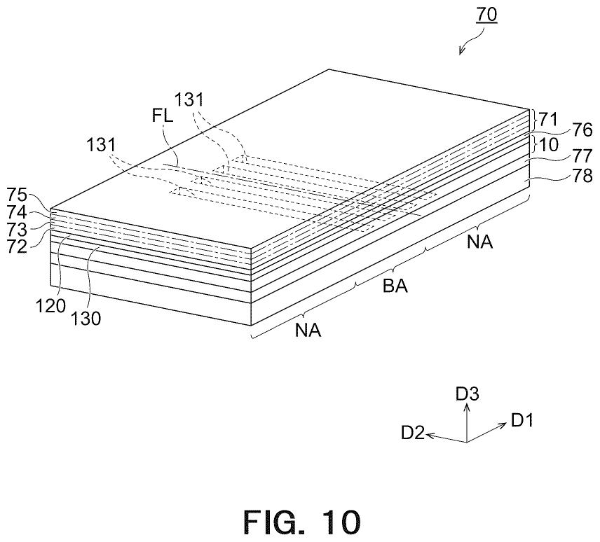

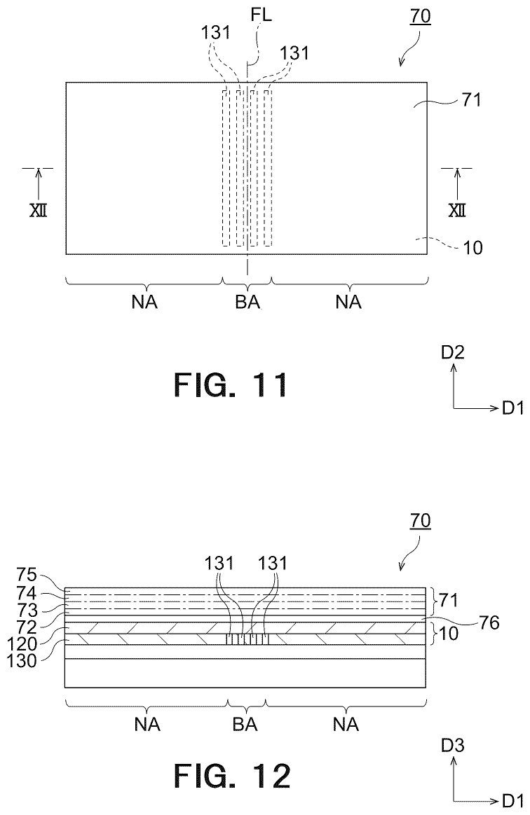

Next, a second embodiment will be described with reference to FIGS. 10 to 25. FIGS. 10 to 25 are diagrams showing the second embodiment. In FIGS. 10 to 25, the same parts as those of the first embodiment shown in FIGS. 1 to 9 are denoted by the same reference numerals, and detailed description thereof will be omitted.

### Structure of Metal Support for Flexible Display Device

FIGS. 10 to 13 are views showing a flexible display device according to this embodiment. A flexible display device 70 shown in FIGS. 10 to 13 includes a display member 71 and a metal support 10 for a flexible display device (hereinbelow, also simply referred to as a metal support 10) that supports the display member 71. The structure of the flexible display device 70 according to this embodiment is the same as the structure of the flexible display device 70 according to the first embodiment except for the metal support 10, and thus detailed description thereof will be omitted here.

### Structure of Metal Support for Flexible Display Device

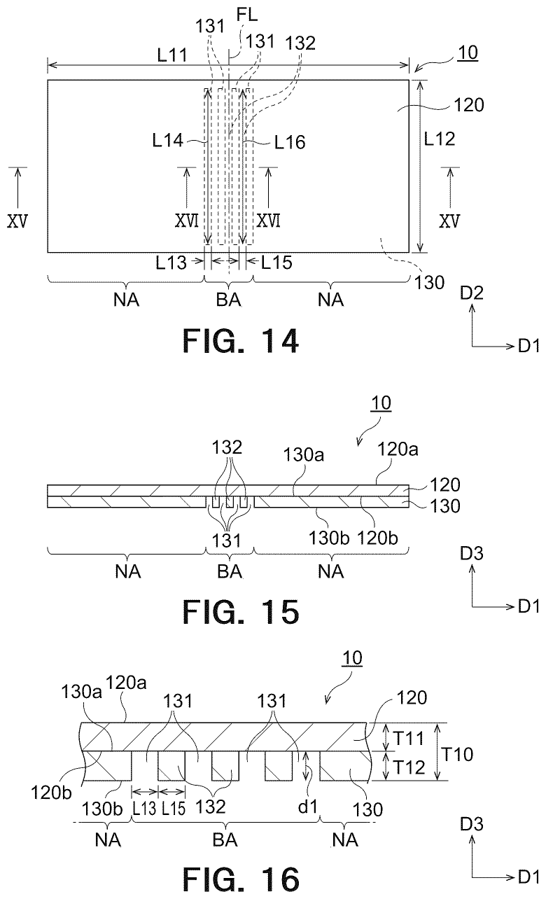

Referring to FIGS. 14 to 16, the outline of the metal support for a flexible display device according to this embodiment will be described. FIGS. 14 to 16 are views showing a metal support for a flexible display device according to this embodiment.

As shown in FIGS. 14 to 16, the metal support 10 includes a first layer 120 and a second layer 130. The metal support 10 is a two-layer laminate. The first layer 120 has a first surface 120a and a second surface 120b. The first surface 120a is a surface facing the display member 71 of the flexible display device 70. The second surface 120b is a surface facing the heat dissipation layer 77 of the flexible display device 70. The first surface 120a and the second surface 120b are each parallel to a plane defined by the first direction D1 axis and the second direction D2 axis. The second layer 130 is bonded to the second surface 120b of the first layer 120. The second layer 130 has a first hole 131 penetrating the second layer 130 in the thickness direction.

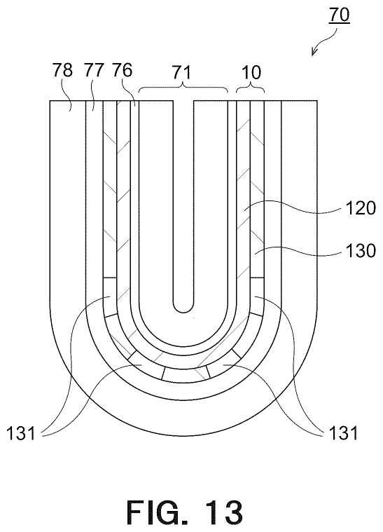

The metal support 10 includes a bending area BA and non-bending areas NA. The bending area BA is an area that is physically deformed when the flexible display device 70 is brought into the folded state (see FIG. 13). The folding center line FL is located at substantially the center of the bending area BA. The non-bending areas NA are areas that are not substantially deformed when the flexible display device 70 is brought into the folded state (see FIG. 13). The bending area BA and the non-bending areas NA correspond to the bending area BA and the non-bending areas NA of the flexible display device 70 described above, respectively.

The first layer 120 may be a member that increases the flexural strength when the flexible display device 70 is folded. The first layer 120 holds the second layer 130. The first layer 120 has no holes. The first layer 120 has a rectangular shape in plan view. In the rectangle, a pair of long sides are parallel to the first direction D1, and a pair of short sides are parallel to the second direction D2. The structure is not limited to this, and the pair of short sides may be parallel to the first direction D1, and the pair of long sides may be parallel to the second direction D2. Corners of the rectangle may be rounded. The first layer 120 may have a square shape, a polygonal shape, or a circular shape in plan view. The shape in plan view of the first layer 120 may correspond to the shape in plan view of the flexible display device 70. The shape in plan view of the first layer 120 may be the same as the shape in plan view of the flexible display device 70. Alternatively, the shape in plan view of the first layer 120 may be smaller than the shape in plan view of the flexible display device 70.

The first layer 120 has a flexible and bendable thin plate shape. In this specification, the term “flexible” means “capable of being folded with a radius of curvature of at least 5.0 mm or less, preferably 3.0 mm or less”.

A length L11 of the first layer 120 in the first direction D1 may be greater than or equal to 100 mm, or may be greater than or equal to 200 mm. The length L11 of the first layer 120 in the first direction D1 may be less than or equal to 500 mm, or may be less than or equal to 400 mm. A length L12 of the first layer 120 in the second direction D2 may be greater than or equal to 50 mm, or may be greater than or equal to 150 mm. The length L12 of the first layer 120 in the second direction D2 may be less than or equal to 400 mm, or may be less than or equal to 350 mm.

A thickness T11 of the first layer 120 may be 30 μm or more, or may be 35 μm or more. By setting the thickness T11 of the first layer 120 to 30 μm or more, the flexural strength of the first layer 120 can be maintained. The thickness T11 of the first layer 120 may be 50 μm or less, or may be 40 μm or less. By setting the thickness T11 of the first layer 120 to 50 μm or less, it is possible to inhibit the flexible display device 70 incorporating the metal support 10 from becoming excessively thick. When the first layer 120 is made of a carbon fiber composite material, the thickness T11 of the first layer 120 may be 10 μm or more, or may be 15 μm or more. When the first layer 120 is made of a carbon fiber composite material, the thickness T11 of the first layer 120 may be 50 μm or less, or may be 40 μm or less.

The main material of the first layer 120 may be a metal material. When the main material of the first layer 120 is a metal material, an iron-based alloy such as stainless steel, copper, a copper alloy, titanium, a titanium-based alloy, magnesium, a magnesium-based alloy, or the like may be used as the metal material. When stainless steel is used as the main metal material of the first layer 120, the first layer 120 has good spring properties, and thus the first layer 120 is easily bent. The main material of the first layer 120 may be a carbon fiber composite material (CFRP) or a resin material. The resin material may be polyimide (PI). In the specification, the “main material” refers to a material contained in a certain member in an amount of more than 50 mass %, preferably more than 80 mass %.

The second layer 130 has a first surface 130a and a second surface 130b. The first surface 130a is a surface facing the display member 71 of the flexible display device 70. The first surface 130a may be referred to as a third surface. The second surface 130b is a surface facing the heat dissipation layer 77 of the flexible display device 70. The second surface 130b may be referred to as a fourth surface. The first surface 130a and the second surface 130b are each parallel to a plane defined by the first direction D1 axis and the second direction D2 axis.

The second layer 130 is bonded to the first layer 120. More specifically, the first surface 130a of the second layer 130 is bonded to the second surface 120b of the first layer 120. The second layer 130 may be directly bonded to the first layer 120, or may be bonded to the first layer 120 with another layer therebetween. The second layer 130 may be bonded to the first layer 120 by, for example, a diffusion bonding method, a bonding method using brazing, a bonding method using an adhesive, an ultrasonic bonding method, or laser welding.

The second layer 130 may increase the strength of the metal support 10. The second layer 130 has a flexible and bendable thin plate shape. The second layer 130 may be provided on the entire second surface 120b of the first layer 120. The shape of the outer periphery of the second layer 130 may be the same as the shape of the outer periphery of the first layer 120. The length of the second layer 130 in the first direction D1 may be equal to the length L11 of the first layer 120 in the first direction D1. The length of the second layer 130 in the second direction D2 may be equal to the length L12 of the first layer 120 in the second direction D2.

A thickness T12 of the second layer 130 may be 30 μm or more, or may be 35 μm or more. By setting the thickness T12 of the second layer 130 to 30 μm or more, the flexural strength of the second layer 130 can be maintained. The thickness T12 of the second layer 130 may be 50 μm or less, or may be 40 μm or less. By setting the thickness T12 of the second layer 130 to 50 μm or less, it is possible to inhibit the flexible display device 70 incorporating the metal support 10 from becoming excessively thick. When the second layer 130 is made of a carbon fiber composite material, the thickness T12 of the second layer 130 may be 10 μm or more, or may be 15 μm or more. When the second layer 130 is made of a carbon fiber composite material, the thickness T12 of the second layer 130 may be 50 μm or less, or may be 40 μm or less.

The main material of the second layer 130 may be a metal material. When the main material of the second layer 130 is a metal material, an iron-based alloy such as stainless steel, copper, a copper alloy, titanium, a titanium-based alloy, magnesium, a magnesium-based alloy, or the like may be used as the metal material. When stainless steel is used as the main metal material of the second layer 130, the second layer 130 has good spring properties, and thus the second layer 130 is easily bent. The main material of the second layer 130 may be a carbon fiber composite material (CFRP) or a resin material. The resin material may be polyimide (PI). The main material of the second layer 130 may be the same as or different from the main material of the first layer 120.

The second layer 130 has a plurality of first holes 131. The plurality of first holes 131 are provided in the bending area BA. The plurality of first holes 131 may be formed in a line shape. The plurality of first holes 131 may be arranged parallel to each other. The shapes in plan view of the plurality of first holes 131 may be equal to or may be different from each other. Each first hole 131 extends linearly in the second direction D2. Each first hole 131 may have a rectangular shape in plan view. The shape of each first hole 131 is not limited thereto, and may be, for example, a polygonal shape or a circular shape in plan view. Each first hole 131 may have a rectangular shape with rounded corners in plan view. Each first hole 131 may be present only in a portion of the second layer 130 in the second direction D2.

Each first hole 131 is open in both the first surface 130a and the second surface 130b. In other words, each first hole 131 is a through-hole penetrating the second layer 130 in the thickness direction. Because the first hole 131 is a through-hole, it is possible to further reduce the radius of curvature of the bending area BA when the metal support 10 is folded, and to increase the bending resistance. Furthermore, the metal support 10 can be further reduced in weight. In the specification, the term “hole” is a concept including both a non-penetrating hole and a through-hole. The structure is not limited thereto, and each first hole 131 only needs to be open at least on the side opposite from the first surface 130a, which is the bonding surface to the first layer 120. In other words, each first hole 131 only needs to be open at least in the second surface 130b.

A length L13 of each first hole 131 in the first direction D1 may be 50 μm or more, or may be 100 μm or more. The length L13 of each first hole 131 in the first direction D1 may be 1000 μm or less, or may be 500 μm or less. A length L14 of each first hole 131 in the second direction D2 may be 200 μm or more, or may be 400 μm or more. The length L14 of each first hole 131 in the second direction D2 may be 2000 μm or less, or may be 1000 μm or less. The length L13 and the length L14 are each the distance in the second surface 130b. A depth d1 of the first hole 131, which is a through-hole, is equal to the thickness T12 of the second layer 130.

The second layer 130 includes a plurality of first bank portions 132 in the bending area BA. Each first bank portion 132 extends linearly in the second direction D2. The plurality of first bank portions 132 are disposed at intervals in the first direction D1. The first holes 131 are formed between the plurality of first bank portions 132. In other words, the first holes 131 and the first bank portions 132 are formed alternately in the first direction D1. In this case, because the first holes 131 and the first bank portions 132 are arranged alternately, it is possible to alleviate stress concentration on a specific portion of the bending area BA when the flexible display device 70 is folded.

The plurality of first bank portions 132 are arranged parallel to each other. The shapes of the plurality of first bank portions 132 may be equal to or may be different from each other. Each first bank portion 132 may have a rectangular shape in plan view. The shape of the first bank portion 132 is not limited thereto, and may be a shape surrounding the first hole 131 in plan view. Each first bank portion 132 may extend over the entire second layer 130 in the second direction D2, or may be present only in a portion of the second layer 130 in the second direction D2. Each first bank portion 132 is not thinned from either the first surface 130a side or the second surface 130b side. The thickness of each first bank portion 132 is equal to the thickness T12 of the second layer 130.

A length L15 of each first bank portion 132 in the first direction D1 may be 50 μm or more, or may be 100 μm or more. The length L15 of each first bank portion 132 in the first direction D1 may be 400 μm or less, or may be 200 μm or less. The length L15 is the distance in the second surface 130b. A length L16 of each first bank portion 132 in the second direction D2 may be equal to the length L14 of each first hole 131 in the second direction D2.

The overall thickness T10 of the metal support 10 may be 50 μm or more, or may be 75 μm or more. By setting the overall thickness T10 of the metal support 10 to 50 μm or more, the rigidity of the metal support 10 can be maintained. The overall thickness T10 of the metal support 10 may be 150 μm or less, or 125 μm or less. By setting the overall thickness T10 of the metal support 10 to 150 μm or less, it is possible to inhibit the metal support 10 from becoming excessively heavy.

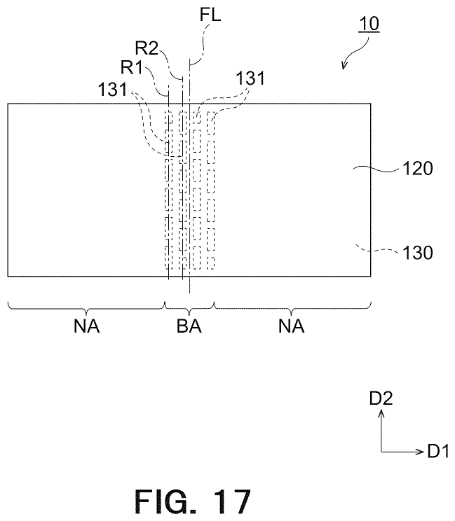

FIG. 17 is a plan view showing a modification of the metal support 10. As shown in FIG. 17, a plurality of first holes 131 may be arranged alternately (in a staggered manner). Each first hole 131 has a substantially rectangular shape in plan view. The shape of each first hole 131 is not limited thereto, and may be, for example, a polygonal shape or a circular shape in plan view. Each first hole 131 may have a rectangular shape with rounded corners in plan view. The plurality of first holes 131 include the first holes 131 in the first row R1 and the first holes 131 in the second row R2. The first holes 131 in the first row R1 are arranged at intervals in the second direction D2. The first holes 131 in the second row R2 are arranged at intervals in the second direction D2. The first holes 131 in the first row R1 and the first holes 131 in the second row R2 are arranged so as to be shifted from each other in the second direction D2. According to this modification, because the plurality of first holes 131 are arranged alternately, it is possible to inhibit the stress from concentrating on a specific portion around a first hole 131 when the flexible display device 70 is folded.

### Method for Manufacturing Metal Support for Flexible Display Device

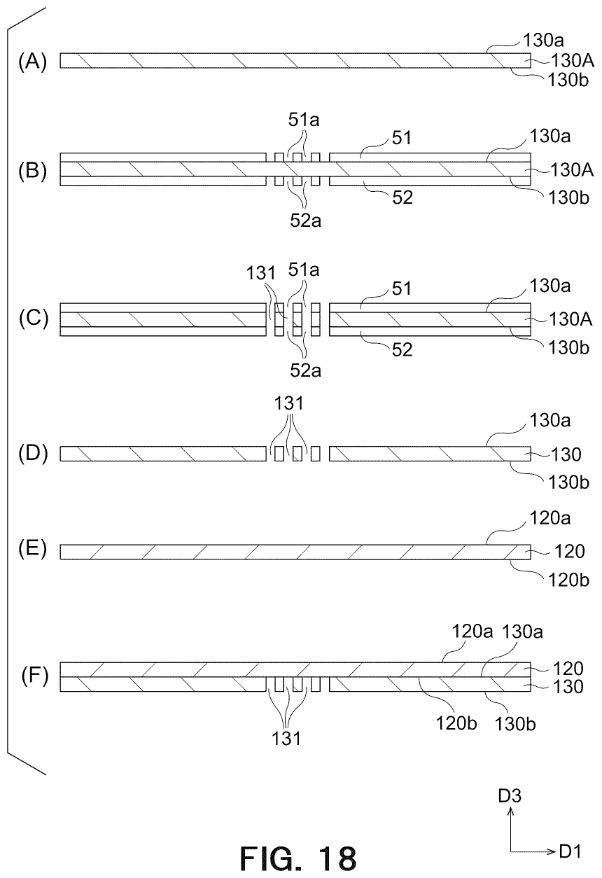

Next, a method for manufacturing the metal support 10 shown in FIGS. 14 and 15 will be described with reference to FIG. 18(A) to 18(F).

First, as shown in FIG. 18(A), a second layer 130A having a first surface 130a and a second surface 130b is prepared. The second layer 130A is in an unprocessed state before being provided with holes.

Next, as shown in FIG. 18(B), the first protective layer 51 and the second protective layer 52 are provided on the second layer 130A. More specifically, the first protective layer 51 having first protective layer openings 51a is provided on the first surface 130a of the second layer 130A, and the second protective layer 52 having second protective layer openings 52a is provided on the second surface 130b of the second layer 130A. The first protective layer 51 and the second protective layer 52 may be resist layers. At this time, first, a photosensitive resist is applied to the entire first surface 130a and the entire second surface 130b of the second layer 130A, and is dried. Subsequently, the photosensitive resist on the first surface 130a and the second surface 130b of the second layer 130A is exposed through a photomask and developed. By doing so, the first protective layer 51 having the first protective layer openings 51a is formed on the first surface 130a of the second layer 130A. The second protective layer 52 having the second protective layer openings 52a is formed on the second surface 130b of the second layer 130A. The shape in plan view of the first protective layer openings 51a and the second protective layer openings 52a correspond to the shape in plan view of the first holes 131. The shape in plan view of the first protective layer openings 51a and the shape in plan view of the second protective layer openings 52a may be equal to or may be different from each other.

Next, as shown in FIG. 18(C), the second layer 130A is etched with an etchant using the first protective layer 51 and the second protective layer 52 as corrosion-resistant films. The etchant can be appropriately selected according to the material of the second layer 130A. For example, when stainless steel is used as the second layer 130A, a mixed solution containing ferric chloride as a main component and mixed with hydrochloric acid, or a mixed solution of the aforementioned solution and nitric acid may be used as the etchant. The etchant may be used to spray-etch the second layer 130A. In this way, the first holes 131 penetrating the second layer 130A are formed in the second layer 130A.

Subsequently, as shown in FIG. 18(D), the first protective layer 51 on the first surface 130a of the second layer 130A and the second protective layer 52 on the second surface 130b are peeled away. In this way, the second layer 130 having a plurality of first holes 131 is obtained. The first holes 131 may be formed by pressing or laser processing.

Next, as shown in FIG. 18(E), a first layer 120 having a first surface 120a and a second surface 120b is prepared. The first layer 120 has no holes.

Next, as shown in FIG. 18(F), the second layer 130 is bonded to the first layer 120. At this time, the first holes 131 are open at least in the second surface 130b, which is located on the opposite side from the bonding surface to the first layer 120. More specifically, the first surface 130a of the second layer 130 is bonded to the second surface 120b of the first layer 120. In this case, the first layer 120 and the second layer 130 may be bonded to each other by a diffusion bonding method. When the diffusion bonding method is used, the second layer 130 is pressure-bonded to the first layer 120 at a temperature close to the melting point. By doing so, metal atoms located near the contact surface between the first layer 120 and the second layer 130 are mutually diffused, and the first layer 120 and the second layer 130 can be bonded to each other. When the diffusion bonding method is used, the overall thickness T10 of the metal support 10 can be reduced. The second layer 130 may be bonded to the first layer 120 by brazing, an adhesive, ultrasonic bonding, or laser welding, for example.

In this way, the metal support 10 shown in FIGS. 14 and 15 is obtained.

According to this embodiment, the metal support 10 includes the first layer 120 and the second layer 130, and the second layer 130 has the first holes 131. This increases the flexibility of the bending area BA of the flexible display device 70 when the metal support 10 is incorporated into the flexible display device 70. As a result, it is possible to make the shape of the bending area BA when the flexible display device 70 is folded even smaller, and to improve the bending resistance. In other words, the radius of curvature of the bending area BA can be further reduced.

Furthermore, according to this embodiment, by bonding the second layer 130 to the first layer 120, it is possible to improve the bending resistance of the metal support 10. In addition, because the thickness T11 of the first layer 120 and the thickness T12 of the second layer 130 can be reduced independently, the first layer 120 and the second layer 130 can be easily processed.

According to this embodiment, the first layer 120 has no holes. In this case, there is no need to consider the workability of the first layer 120, so, various materials for the first layer 120 can be selected. For example, by selecting a light material for the first layer 120, the weight of the entire metal support 10 can be reduced. The material of the first layer 120 may be a material having high affinity for the buffer layer 76 or an adhesive layer for attaching the metal support 10 to the buffer layer 76. The adhesive layer may be a transparent adhesive layer such as an optical clear adhesive (OCA) layer.

According to this embodiment, the first layer 120 has no holes. In this case, the surface of the metal support 10 facing the display member 71 of the flexible display device 70 has no irregularities. This can suppress the influence of the unevenness caused by holes in the metal support 10 on the display member 71. Thus, it is possible to improve the flatness of the flexible display device 70.

Furthermore, according to this embodiment, because the second layer 130 has the first holes 131, it is possible to reduce the weight of the metal support 10.

Furthermore, according to this embodiment, the second layer 130 is provided with the first holes 131 in advance, and then the second layer 130 is bonded to the first layer 120. Because the second layer 130 can be processed in a state before being stacked, various materials can be selected as the material of the second layer 130. For example, materials other than the combination of materials that can be selectively etched can be used as the materials of the first layer 120 and the second layer 130. In addition, because the second layer 130 can be processed in a state before being stacked, the second layer 130 is easily processed.

According to this embodiment, the second layer 130 may be provided with the first holes 131 by etching in advance, and then the second layer 130 may be diffusion-bonded to the first layer 120. By doing so, even when the interface between the first layer 120 and the second layer 130 is alloyed by heat during diffusion bonding, the alloyed portion does not affect etching.

### Modification of Second Embodiment

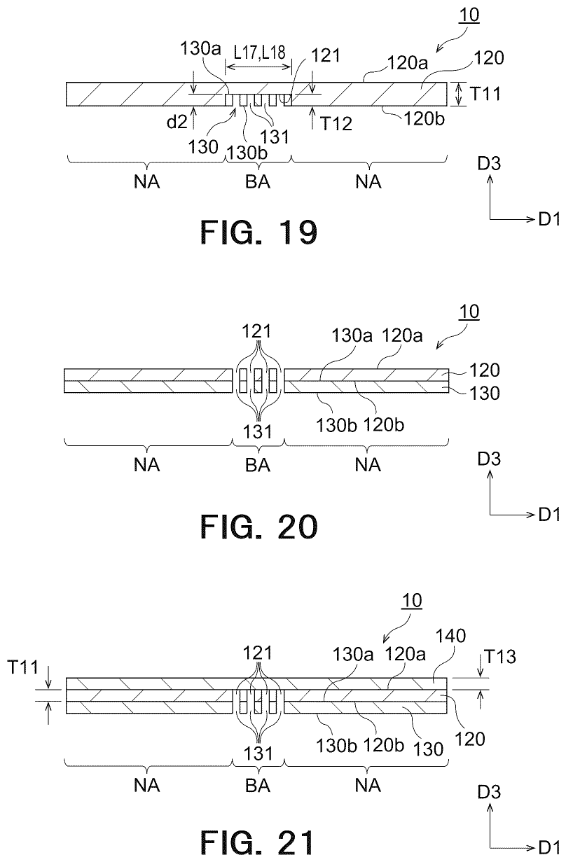

Next, various modifications of this embodiment will be described with reference to FIGS. 19 to 25. FIGS. 18 to 25 are diagrams showing modifications of this embodiment. In FIGS. 18 to 25, the same parts as those in the embodiment shown in FIGS. 10 to 17 are denoted by the same reference numerals, and detailed description thereof will be omitted. In the embodiment shown in FIGS. 10 to 17 and the modifications shown in FIGS. 19 to 25, the first layers may have substantially the same structure, the second layers may have substantially the same structure, and the third layers may have substantially the same structure, unless otherwise specified. For example, the first layers in the modifications may be made of the same material as the first layer of the embodiment shown in FIGS. 10 to 17. The second layers in the modifications may be made of the same material as the second layer of the embodiment shown in FIGS. 10 to 17.

### First Modification of Second Embodiment

As shown in FIG. 19, the first layer 120 may have a second hole 121, and the second layer 130 may be accommodated in the second hole 121. The shape in plan view of the second layer 130 is smaller than the shape in plan view of the first layer 120. A length L17 of the second layer 130 in the first direction D1 may be greater than or equal to 5 mm, or may be greater than or equal to 10 mm. The length L17 of the second layer 130 in the first direction D1 may be less than or equal to 30 mm, or may be less than or equal to 25 mm. The length of the second layer 130 in the second direction D2 may be equal to the length L12 of the first layer 120 in the second direction D2, or may be shorter than L12. The thickness T12 of the second layer 130 is less than the thickness T11 of the first layer 120. The thickness T11 of the first layer 120 may be 50 μm or more, or may be 75 μm or more. The thickness T11 of the first layer 120 may be 150 μm or less, or may be 125 μm or less.

The main material of the first layer 120 may be a metal material, a carbon fiber composite material (CFRP), or a resin material. The main material of the second layer 130 may be a metal material, a carbon fiber composite material (CFRP), or a resin material. The resin material may be polyimide (PI). A material having a lower density than the main material of the second layer 130 is preferably used as the main material of the first layer 120. For example, it is preferable that a carbon fiber composite material (CFRP), polyimide (PI), titanium, a titanium-based alloy, magnesium, a magnesium-based alloy, or the like be used as the main material of the first layer 120, and an iron-based alloy such as stainless steel, copper, a copper alloy, or the like be used as the main material of the second layer 130.

The second hole 121 is formed in the second surface 120b of the first layer 120. The second hole 121 is a non-penetrating hole that does not penetrate the first layer 120 in the thickness direction. The second hole 121 only needs to be open at least on the second surface 120b side. A part or all of the second hole 121 is present in the bending area BA. A part of the second hole 121 may or may not be present in the non-bending area NA. The shape in plan view of the outer periphery of the second hole 121 may be the same as the shape in plan view of the outer periphery of the second layer 130. The second hole 121 may be formed in a rectangular shape in plan view. The second hole 121 may have, for example, a polygonal shape or a circular shape in plan view. The second hole 121 may have a rectangular shape with rounded corners in plan view. There may be only one or more than one second hole 121 in the first layer 120.

A length L18 of the second hole 121 in the first direction D1 may be equal to the length L17 of the second layer 130 in the first direction D1, or may be longer than L17. The length of the second hole 121 in the second direction D2 may be equal to the length L12 of the first layer 120 in the second direction D2, or may be shorter than L12. A depth d2 of the second hole 121 may be equal to the thickness T12 of the second layer 130, or may be larger than the thickness T12 of the second layer 130. The depth d2 of the second hole 121 may be 30% or more of the thickness T11 of the first layer 120, or may be 40% or more. The depth d2 of the second hole 121 may be 90% or less of the thickness T11 of the first layer 120, or may be 80% or less. The second hole 121 may be formed by half etching. In the specification, “half etching” means etching a material to be etched halfway in the thickness direction thereof. The thickness of the material to be etched after the half etching is, for example, 30% or more and 90% or less, and preferably 40% or more and 80% or less of the thickness of the material to be etched before the half etching. The second hole 121 may be formed by press working or laser processing.

According to this modification, the first layer 120 can be disposed in the entirety or a large part of the non-bending area NA. Thus, by selecting a material having a low density or a high rigidity material as the material of the first layer 120, the metal support 10 can be made lightweight or highly rigid as a whole.

### Second Modification of Second Embodiment

As shown in FIG. 20, the first layer 120 may have a plurality of second holes 121, and each second hole 121 may overlap the corresponding first hole 131 in plan view. All of the second holes 121 may overlap the corresponding first holes 131, or only some of the second holes 121 may overlap the first holes 131. The plurality of second holes 121 are provided in the bending area BA. Each second hole 121 is a through-hole penetrating the first layer 120 in the thickness direction. The shape in plan view of each second hole 121 may be equal to or different from the shape in plan view of each first hole 131. The second holes 121 may be formed by etching or may be formed by press working or laser processing.

According to this modification, because the first layer 120 has the plurality of second holes 121, it is possible to reduce the weight of the metal support 10 as a whole. In addition, because the first layer 120 has the plurality of second holes 121, it is possible to increase the flexibility of the bending area BA of the metal support 10. This further reduces the radius of curvature of the bending area BA when the flexible display device 70 is folded and increases the bending resistance when the metal support 10 is incorporated into the flexible display device 70.

### Third Modification of Second Embodiment

As shown in FIG. 21, the metal support 10 may include a third layer 140 bonded to the first surface 120a of the first layer 120. In this case, the metal support 10 is a three-layer laminate. The third layer 140 is located on the opposite side of the first layer 120 from the second layer 130. The third layer 140 may be bonded to the first layer 120 by a diffusion bonding method, a bonding method using brazing, a bonding method using an adhesive, an ultrasonic bonding method, or laser welding. The third layer 140 may be provided on the entire first surface 120a of the first layer 120, or may be provided on a part of the first surface 120a of the first layer 120. A thickness T13 of the third layer 140 may be 30 μm or more, or may be 35 μm or more. The thickness T13 of the third layer 140 may be 50 μm or less, or may be 40 μm or less. The thickness T13 of the third layer 140 may be equal to or different from the thickness T11 of the first layer 120.

The main material of the third layer 140 may be a metal material. When the main material of the third layer 140 is a metal material, an iron-based alloy such as stainless steel, copper, a copper alloy, titanium, a titanium-based alloy, magnesium, a magnesium-based alloy, or the like may be used as the metal material. The main material of the third layer 140 may be a carbon fiber composite material (CFRP) or a resin material. The resin material may be polyimide (PI). The main material of the third layer 140 may be the same as or different from the main material of the first layer 120. The other structures may be the same as those of the second modification (FIG. 20).

According to this modification, the third layer 140 is bonded to the first surface 120a of the first layer 120. By uniformly sandwiching the first layer 120 between the second layer 130 and the third layer 140 in this way, it is possible to inhibit the metal support 10 before being incorporated into the flexible display device 70 from warping.

### Fourth Modification of Second Embodiment

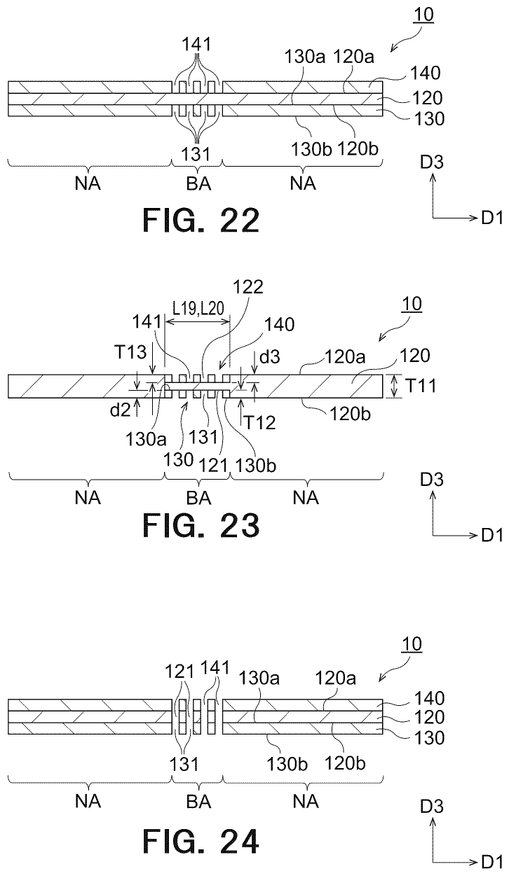

As shown in FIG. 22, the metal support 10 may include a third layer 140 bonded to the first surface 120a of the first layer 120. The third layer 140 has a plurality of third holes 141. Each third hole 141 may or may not overlap the first hole 131 in plan view. The plurality of third holes 141 are provided in the bending area BA. Each third hole 141 is a through-hole penetrating the third layer 140 in the thickness direction. The shape in plan view of each third hole 141 may be equal to or different from the shape in plan view of each first hole 131. The third hole 141 may be formed by etching or may be formed by press working or laser processing.

According to this modification, the third layer 140 is bonded to the first surface 120a of the first layer 120. By uniformly sandwiching the first layer 120 between the second layer 130 and the third layer 140 in this way, it is possible to inhibit the metal support 10 from warping. The third layer 140 has the third holes 141. This not only makes it easy to fold the metal support 10 such that the third layer 140 side is on the inner side, but also makes it easy to fold the metal support 10 such that the second layer 130 is on the inner side. In addition, the presence of the third holes 141 in the bending area BA can improve the adhesion between the third layer 140 and the adhesive layer for attaching the metal support 10 to the buffer layer 76. Thus, it is possible to inhibit the metal support 10 and the buffer layer 76 from peeling away from each other.

### Fifth Modification of Second Embodiment

As shown in FIG. 23, the first layer 120 may have a second hole 121, and the second layer 130 may be accommodated in the second hole 121. The first layer 120 may have a fourth hole 122, and the third layer 140 may be accommodated in the fourth hole 122. The third layer 140 has a plurality of third holes 141. The shapes in plan view of the second layer 130 and the third layer 140 are smaller than the shape in plan view of the first layer 120. The shape in plan view of the third layer 140 may be equal to or different from the shape in plan view of the second layer 130. A length L19 of the third layer 140 in the first direction D1 may be greater than or equal to 5 mm, or may be greater than or equal to 10 mm. The length L19 of the third layer 140 in the first direction D1 may be less than or equal to 30 mm, or may be less than or equal to 25 mm. The length of the third layer 140 in the second direction D2 may be equal to the length L12 of the first layer 120 in the second direction D2, or may be shorter than L12. The thickness T13 of the third layer 140 is less than the thickness T11 of the first layer 120. The thickness T13 of the third layer 140 may be 15% or more and 45% or less of the thickness T11 of the first layer 120. The thickness T12 of the second layer 130 may be 15% or more and 45% or less of the thickness T11 of the first layer 120. The thickness T13 of the third layer 140 may be equal to or different from the thickness T12 of the second layer 130.

The fourth hole 122 is formed in the first surface 120a of the first layer 120. The fourth hole 122 is a non-penetrating hole that does not penetrate the first layer 120 in the thickness direction. A part or all of the fourth hole 122 is present in the bending area BA. A part of the fourth hole 122 may or may not be present in the non-bending area NA. The shape in plan view of the outer periphery of the fourth hole 122 may be the same as the shape in plan view of the outer periphery of the third layer 140. The fourth hole 122 may be formed in a rectangular shape in plan view. The fourth hole 122 may have, for example, a polygonal shape or a circular shape in plan view. The fourth hole 122 may have a rectangular shape with rounded corners in plan view. There may be only one or more than one fourth hole 122 in the first layer 120. The shape in plan view of the fourth hole 122 may be equal to or different from the shape in plan view of the second hole 121. The fourth hole 122 may overlap or may be shifted from the second hole 121 in plan view.

A length L20 of the fourth hole 122 in the first direction D1 may be equal to the length L19 of the third layer 140 in the first direction D1, or may be longer than L19. The length of the fourth hole 122 in the second direction D2 may be equal to the length L12 of the first layer 120 in the second direction D2, or may be shorter than L12. A depth d3 of the fourth hole 122 may be equal to the thickness T13 of the third layer 140, or may be larger than the thickness T13 of the third layer 140. The depth d3 of the fourth hole 122 may be 15% or more of the thickness T11 of the first layer 120, or may be 20% or more. The depth d3 of the fourth hole 122 may be 45% or less of the thickness T11 of the first layer 120, or may be 40% or less. The depth d3 of the fourth hole 122 may be equal to or different from the depth d2 of the second hole 121. The fourth hole 122 may be formed by half etching. The fourth hole 122 may be formed by press working or laser processing. The other structures may be the same as those in the first modification (FIG. 19).

According to this modification, the second layer 130 is accommodated in the second hole 121, and the third layer 140 is accommodated in the fourth hole 122. By sandwiching the first layer 120 between the second layer 130 and the third layer 140 in this way, it is possible to inhibit the metal support 10 from warping. The third layer 140 has the third holes 141. This not only makes it easy to fold the metal support 10 such that the third layer 140 side is on the inner side, but also makes it easy to fold the metal support 10 such that the second layer 130 is on the inner side. In addition, the presence of the third holes 141 in the bending area BA can improve the adhesion between the third layer 140 and the adhesive layer for adhering the metal support 10 to the display member 71. This can inhibit the metal support 10 and the display member 71 from peeling away from each other. Furthermore, according to this modification, the first layer 120 can be disposed in the entirety or a large part of the non-bending area NA. Thus, by selecting a material having a low density or a high rigidity material as the material of the first layer 120, the metal support 10 can be made lightweight or highly rigid as a whole.

### Sixth Modification of Second Embodiment

As shown in FIG. 24, the metal support 10 may include a third layer 140 bonded to the first surface 120a of the first layer 120. The third layer 140 has a plurality of third holes 141. The first layer 120 has a plurality of second holes 121. The first holes 131, the second holes 121, and the third holes 141 may or may not overlap each other in plan view. The plurality of second holes 121 are provided in the bending area BA. Each second hole 121 is a through-hole penetrating the first layer 120 in the thickness direction. The plurality of third holes 141 are provided in the bending area BA. Each third hole 141 is a through-hole penetrating the third layer 140 in the thickness direction. The shapes in plan view of the first holes 131, the second holes 121, and the third holes 141 may be equal to or different from each other. The other structures may be the same as those of the fourth modification (FIG. 22).

According to this modification, the third layer 140 is bonded to the first surface 120a of the first layer 120. By uniformly sandwiching the first layer 120 between the second layer 130 and the third layer 140 in this way, it is possible to inhibit the metal support 10 from warping. The third layer 140 has the third holes 141. This not only makes it easy to fold the metal support 10 such that the third layer 140 side is on the inner side, but also makes it easy to fold the metal support 10 such that the second layer 130 is on the inner side. In addition, the presence of the third holes 141 in the bending area BA can improve the adhesion between the third layer 140 and the adhesive layer for adhering the metal support 10 to the display member 71. This can inhibit the metal support 10 and the display member 71 from peeling away from each other. In addition, because the first layer 120 has the plurality of second holes 121, it is possible to increase the flexibility of the bending area BA of the metal support 10. Furthermore, the metal support 10 can be further reduced in weight.

### Seventh Modification of Second Embodiment

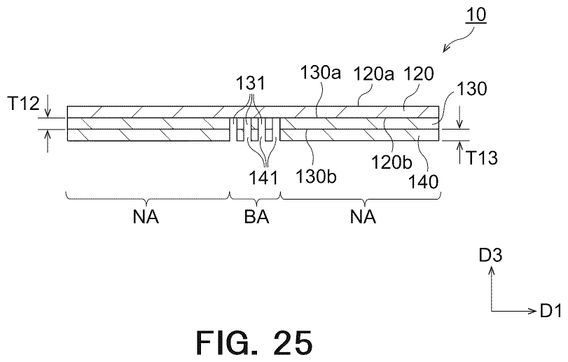

As shown in FIG. 25, the metal support 10 may include a third layer 140 bonded to the second surface 130b of the second layer 130. The third layer 140 is located on the opposite side of the second layer 130 from the first layer 120. The third layer 140 may be bonded to the second layer 130 by a diffusion bonding method, a bonding method using brazing, a bonding method using an adhesive, an ultrasonic bonding method, or laser welding. The third layer 140 may be provided on the entire second surface 130b of the second layer 130, or may be provided on a part of the second surface 130b of the second layer 130. The third layer 140 has a plurality of third holes 141. Each third hole 141 may or may not overlap the first hole 131 in plan view. The plurality of third holes 141 are provided in the bending area BA. Each third hole 141 is a through-hole penetrating the third layer 140 in the thickness direction. The other structures may be the same as those of the fourth modification (FIG. 22).

A plurality of components disclosed in the above-described embodiments and modifications may be appropriately combined as necessary. Alternatively, some of the components may be omitted from all the components described in the above embodiments and modifications.

1. A metal support for a flexible display device, the metal support comprising:
a first metal layer having a first surface and a second surface; and
a second metal layer stacked on the second surface of the first metal layer, wherein
a main metal material constituting the first metal layer and a main metal material constituting the second metal layer are different from each other, and
the second metal layer has a first opening.

2. The metal support for a flexible display device according to claim 1, further comprising a third metal layer stacked on the first surface of the first metal layer.

3. The metal support for a flexible display device according to claim 2, wherein the third metal layer has a second opening.

4. The metal support for a flexible display device according to claim 3, wherein at least a part of the first opening in the second metal layer and at least a part of the second opening in the third metal layer overlap each other in plan view.

5. The metal support for a flexible display device according to claim 3, wherein at least a part of the first opening in the second metal layer and at least a part of the second opening in the third metal layer are shifted from each other in plan view.

6. The metal support for a flexible display device according to claim 3, wherein the third metal layer has no opening.

7. The metal support for a flexible display device according to claim 1, wherein the second metal layer has a pattern shape portion around the first opening, and the pattern shape portion includes a portion formed in an island shape, a line shape, or a mesh shape.

8. A flexible display device comprising:
a display member; and
the metal support for a flexible display device according to claim 1 that supports the display member.

9. A method for manufacturing a metal support for a flexible display device, the method comprising:
a step of preparing a laminate including a first metal layer having a first surface and a second surface, and a second metal layer stacked on the second surface of the first metal layer, a main metal material constituting the first metal layer and a main metal material constituting the second metal layer being different from each other;
a step of providing a second protective layer having a second protective layer opening on the second metal layer of the laminate; and
a step of etching the second metal layer of the laminate to form a first opening in the second metal layer.

10. The method for manufacturing a metal support for a flexible display device according to claim 9, wherein
the laminate further includes a third metal layer stacked on the first surface of the first metal layer, and
the method for manufacturing a metal support for a flexible display device further includes a step of providing a first protective layer on the third metal layer.

11. The method for manufacturing a metal support for a flexible display device according to claim 10, wherein
the first protective layer has a first protective layer opening, and
in the step of etching, a second opening is formed in the third metal layer.

12. The method for manufacturing a metal support for a flexible display device according to claim 10, wherein
the first protective layer has no opening, and
in the step of etching, a second opening is not formed in the third metal layer.

13. A metal support for a flexible display device, the metal support comprising:
a first layer having a first surface and a second surface; and
a second layer bonded to the second surface of the first layer,
wherein the second layer has a first hole that is open at least on a side opposite from a bonding surface to the first layer.

14. The metal support for a flexible display device according to claim 13, wherein the first layer has no hole.

15. The metal support for a flexible display device according to claim 13, wherein the first hole is a through-hole.

16. The metal support for a flexible display device according to claim 13, wherein the first layer has a second hole.

17. The metal support for a flexible display device according to claim 16, wherein the second hole is open at least on the second surface side, and the second layer is accommodated in the second hole.

18. The metal support for a flexible display device according to claim 16, wherein the second hole overlaps the first hole in plan view.

19. The metal support for a flexible display device according to claim 13, further comprising a third layer bonded to the first surface of the first layer.

20. The metal support for a flexible display device according to claim 19, wherein the third layer has a third hole.

21. The metal support for a flexible display device according to claim 19, wherein the first layer has a fourth hole, and the third layer is accommodated in the fourth hole.

22. The metal support for a flexible display device according to claim 13, further comprising a third layer bonded to the second layer.

23. A flexible display device comprising:
a display member; and
the metal support for a flexible display device according to claim 13 that supports the display member.

24. A method for manufacturing a metal support for a flexible display device, the method comprising:
a step of preparing a second layer having a first hole;
a step of preparing a first layer having a first surface and a second surface; and
a step of bonding the second layer to the second surface of the first layer such that the first hole is open at least on a side opposite from a bonding surface to the first layer.
